(19) United States
(12) Patent Application Publication
(10) Pub. No.: US 2025/0386550 A1
(43) Pub. Date: Dec. 18, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Han YEH, Hsinchu (TW); Ping-Cheng SUNG, Hsinchu (TW); Yu-Chi CHEN, Taoyuan (TW); Chia-Hsien CHANG, Changhua (TW)

(21) Appl. No.: 18/901,043

(22) Filed: Sep. 30, 2024

Related U.S. Application Data
(60) Provisional application No. 63/661,087, filed on Jun. 18, 2024.

(51) Int. Cl. H01L 29/423; H01L 21/768; H01L 21/8234; H01L 23/532; H01L 27/088; H01L 29/06; H01L 29/08; H01L 29/417; H01L 29/66; H01L 29/775; H01L 29/786

(52) U.S. Cl. CPC H10D 30/6735; H01L 21/76805; H01L 23/5329; H10D 30/014; H10D 30/43; H10D 30/6757; H10D 62/121; H10D 62/151; H10D 64/251; H10D 84/0135; H10D 84/0149; H10D 84/038; H10D 84/83

(57) ABSTRACT

Embodiments of the present disclosure provide a semiconductor device structure and methods of forming the same. The structure includes a gate electrode layer disposed over a substrate, a source/drain region disposed over the substrate, a conductive contact disposed over the source/drain region, a first etch stop layer disposed on the conductive contact and the gate electrode layer, and the first etch stop layer includes SiCN or SiOCN. The structure further includes a first dielectric layer disposed on the first etch stop layer, a first conductive feature disposed in the first dielectric layer and the first etch stop layer, and the first conductive feature is electrically connected to the conductive contact. The structure further includes a second conductive feature disposed in the first dielectric layer and the first etch stop layer, and the second conductive feature is electrically connected to the gate electrode layer.

### CROSS-REFERENCE TO RELATED APPLICATIONS

This application claims priority to U.S. Provisional Application Ser. No. 63/661,087 filed Jun. 18, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6 are perspective views of various stages of manufacturing a semiconductor device structure, in accordance with some embodiments.

FIGS. 7A, 8A, 9A, 10A, 11A, and 12A are cross-sectional side views of various stages of manufacturing the semiconductor device structure taken along line A-A of FIG. 6, in accordance with some embodiments.

FIGS. 7B, 8B, 9B, 10B, 11B, and 12B are cross-sectional side views of various stages of manufacturing the semiconductor device structure taken along line B-B of FIG. 6, in accordance with some embodiments.

FIGS. 7C, 8C, 9C, 10C, 11C, and 12C are cross-sectional side views of various stages of manufacturing the semiconductor device structure taken along line C-C of FIG. 6, in accordance with some embodiments.

FIGS. 13A, 13B, 13C, and 13D are cross-sectional side views of various stages of manufacturing the semiconductor device structure taken along line A-A of FIG. 6, in accordance with some embodiments.

FIGS. 14A, 14B, 14C, and 14D are cross-sectional side views of various stages of manufacturing the semiconductor device structure taken along line A-A of FIG. 6, in accordance with alternative embodiments.

FIGS. 15A, 15B, 15C, 15D, 15E, 15F, and 15G are cross-sectional side views of various stages of manufacturing the semiconductor device structure taken along line A-A of FIG. 6, in accordance with alternative embodiments.

FIGS. 16A and 16B are cross-sectional side views of various stages of manufacturing the semiconductor device structure taken along line A-A of FIG. 6, in accordance with alternative embodiments.

FIGS. 17A, 17B, 17C, 17D, and 17E are cross-sectional side views of various stages of manufacturing the semiconductor device structure taken along line A-A of FIG. 6, in accordance with alternative embodiments.

FIG. 18 is a cross-sectional side view of one of various stages of manufacturing the semiconductor device structure taken along line A-A of FIG. 6, in accordance with alternative embodiments.

FIGS. 19A, 19B, 19C, and 19D are cross-sectional side views of various stages of manufacturing the semiconductor device structure taken along line A-A of FIG. 6, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

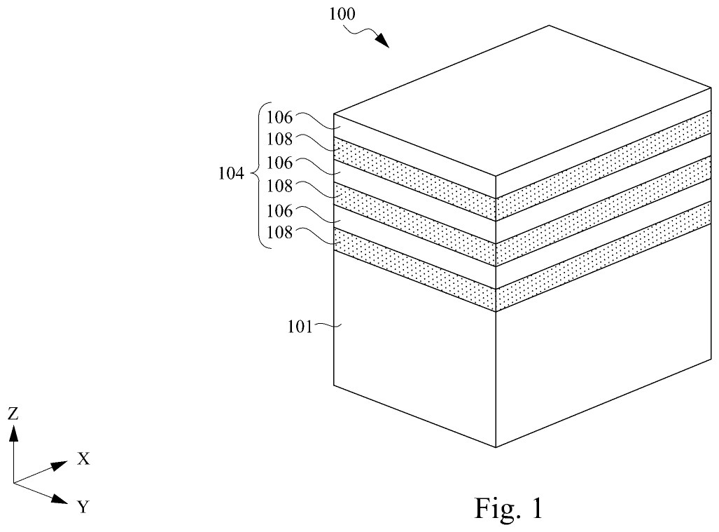

FIGS. 1-13D show exemplary processes for manufacturing a semiconductor device structure 100 according to embodiments of the present disclosure. It is understood that additional operations can be provided before, during, and after processes shown by FIGS. 1-13D, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

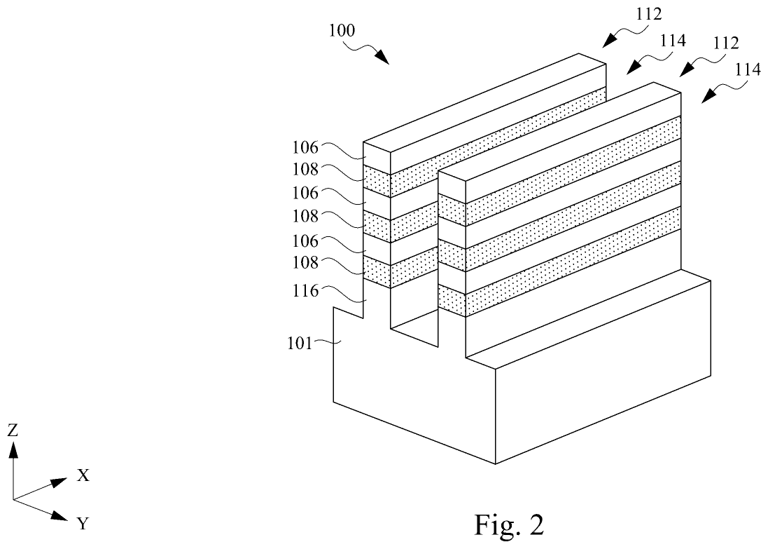

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

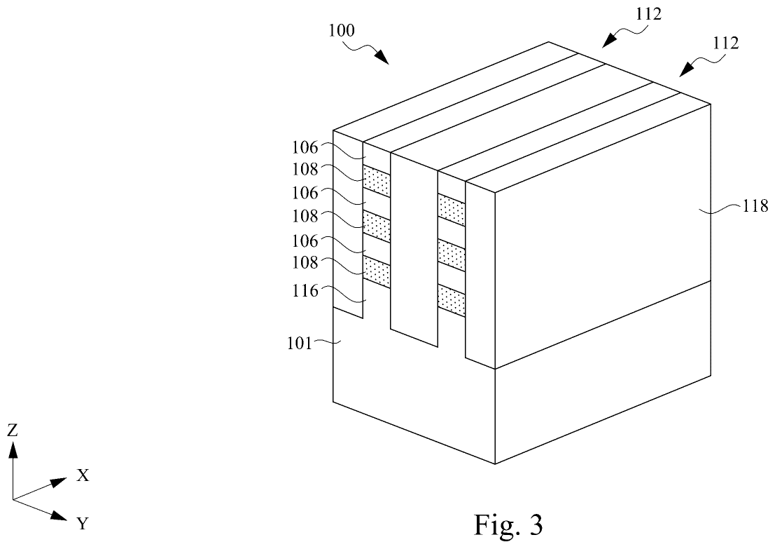

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

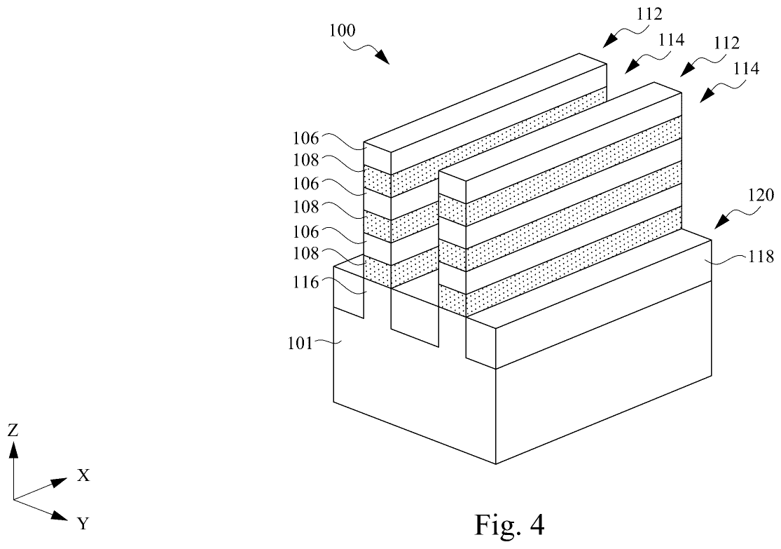

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

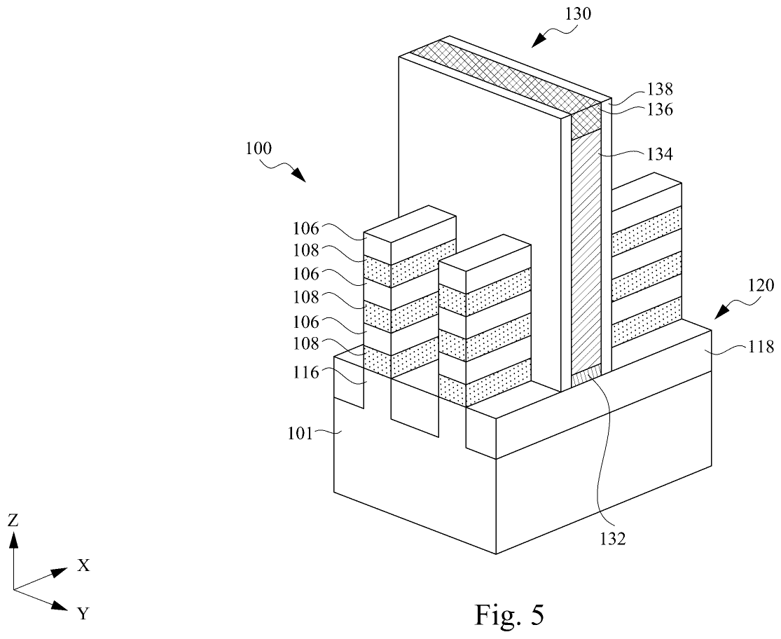

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Spacers 138 are then formed on sidewalls of the sacrificial gate structures 130. The spacers 138 may be formed by conformally depositing one or more layers for the spacers 138 and anisotropically etching the one or more layers, for example. In some embodiments, the spacers 138 are also formed on sidewalls of the exposed portions of the fin structures 112. While one sacrificial gate structure 130 is shown, two or more sacrificial gate structures 130 may be arranged along the X direction in some embodiments. In some embodiments, a contact poly pitch (CPP), which is a minimum center-to-center distance between adjacent sacrificial gate electrode layers 134, ranges from about 35 nm to about 100 nm.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

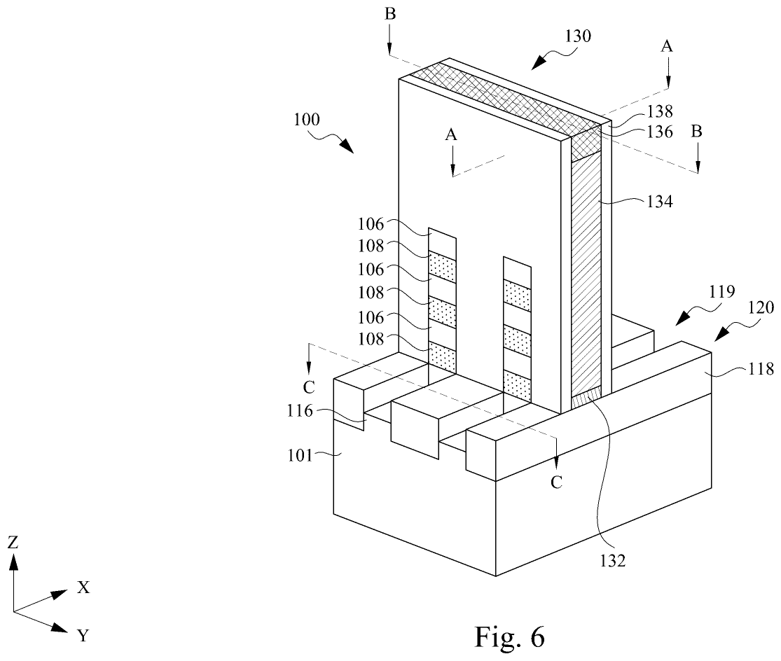

In FIG. 6, the portions of the fin structures 112 not covered by the sacrificial gate structure 130 and the spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

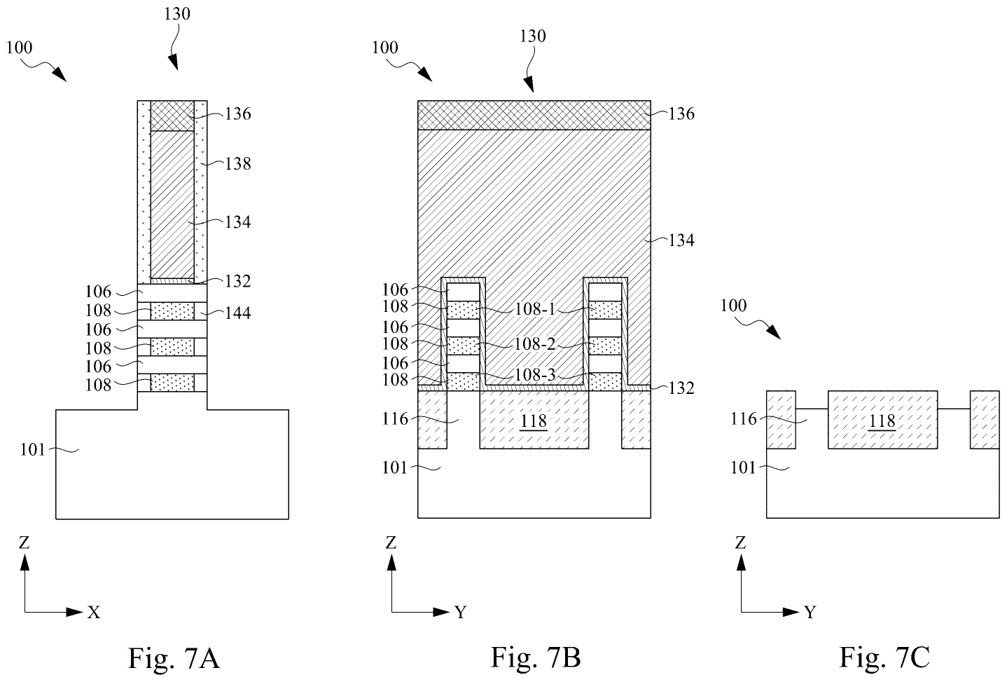

FIGS. 7A, 7B, and 7C are cross-sectional side views of the semiconductor device structure 100 taken along line A-A, line B-B, and line C-C of FIG. 6, respectively.

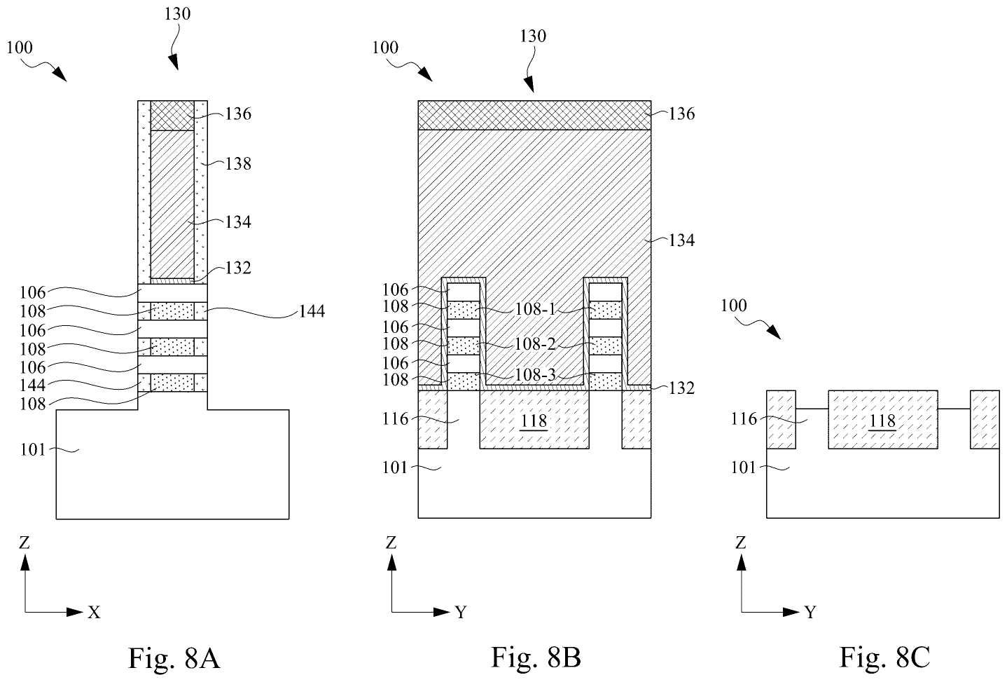

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

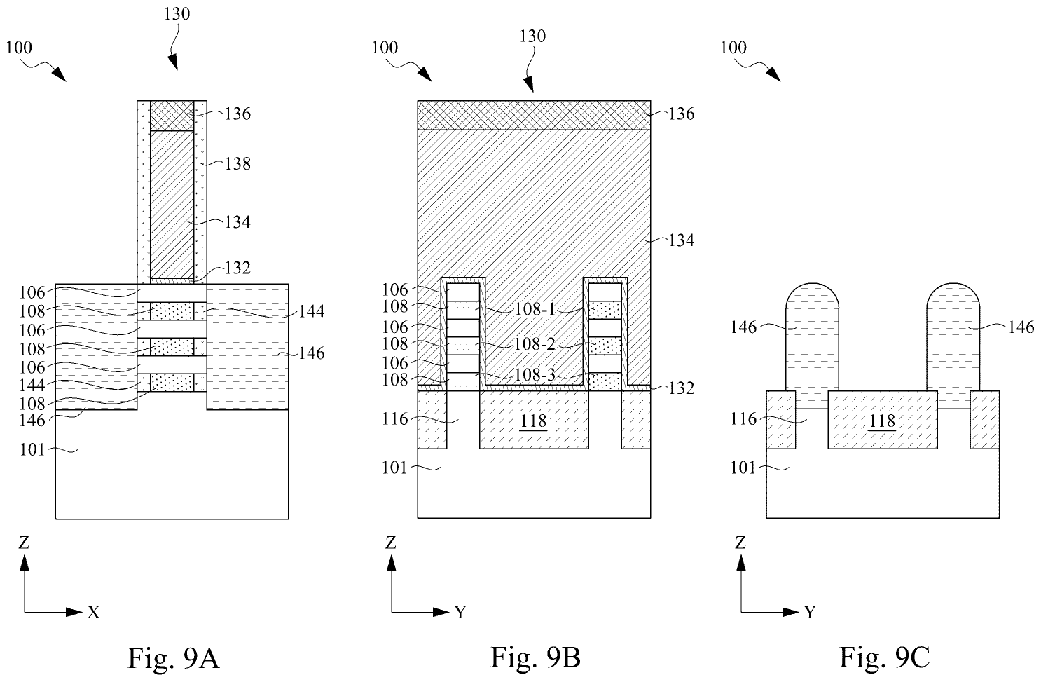

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

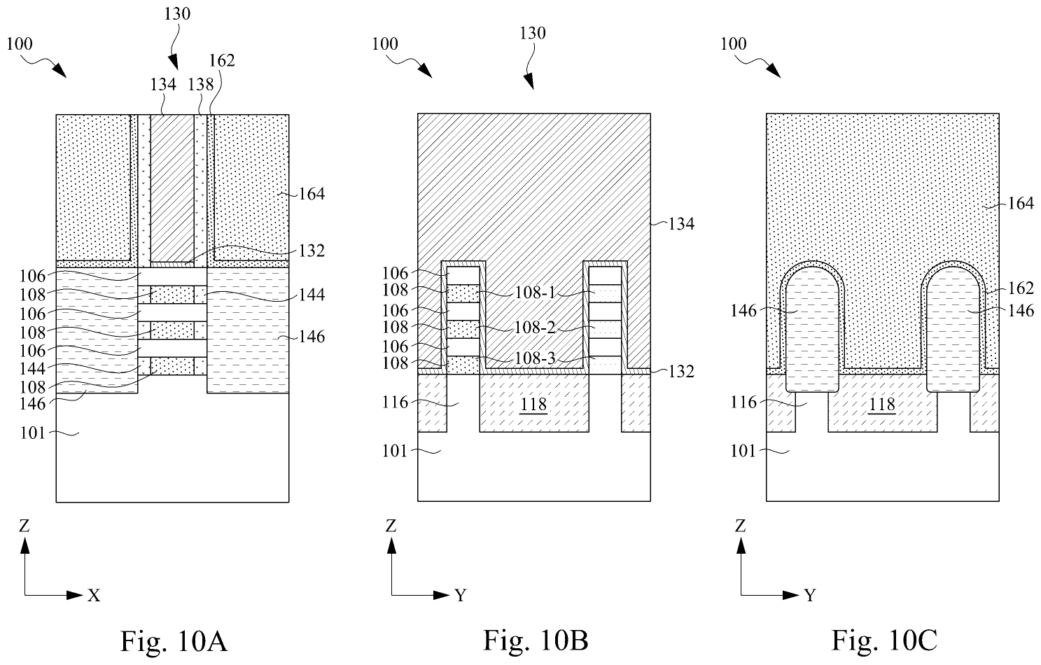

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include a nitrogen-containing material, such as silicon nitride, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, the k value of the ILD layer 164 is less than 4, such as from about 2.5 to about 3.5. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

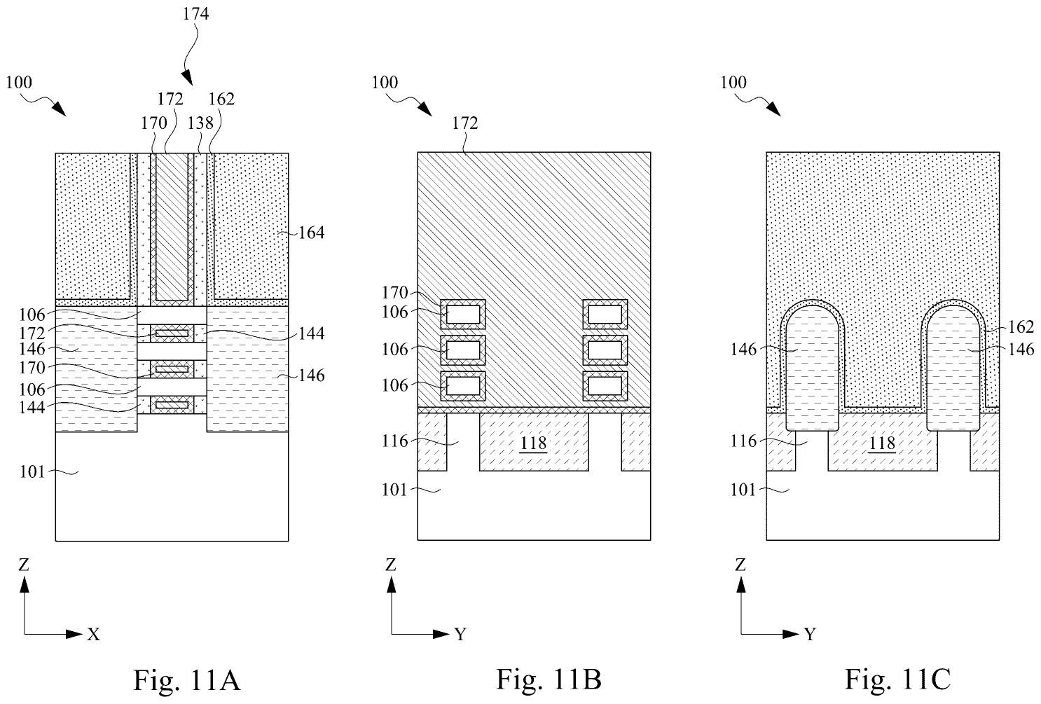

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between the spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

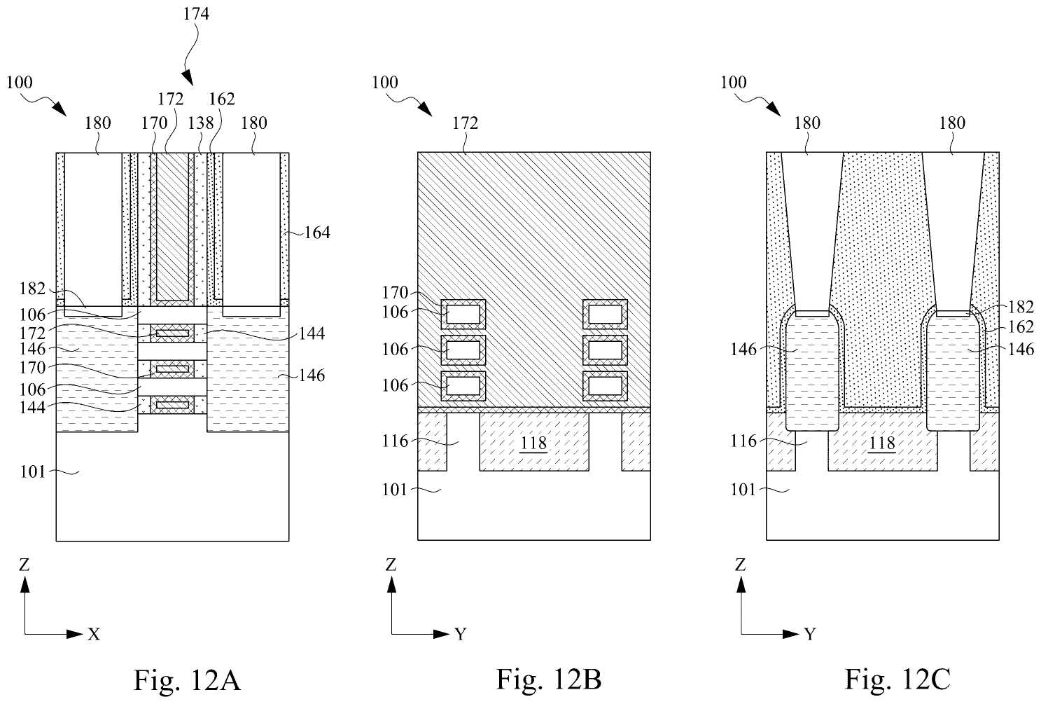

FIGS. 12A, 12B, and 12C are cross-sectional side views of one of various stages of manufacturing the semiconductor device structure 100 taken along line A-A, line B-B, and line C-C of FIG. 6, respectively, in accordance with some embodiments. As shown in FIGS. 12B and 12C, conductive contacts 180 are formed in the ILD layer 164 and the CESL 162. The conductive contacts 180 are electrically connected to the corresponding S/D regions 146 via silicide layers 182. The conductive contact 180 may be electrically conductive and may include a material having one or more of Ru, Mo, Co, Ir, W, Ti, Ta, Cu, TiN or TaN. The conductive contacts 180 may be formed by any suitable method, such as electro-chemical plating (ECP) or PVD. The silicide layers 182 may be formed by any suitable process. In some embodiments, a metal layer (not shown) is first formed on the semiconductor device structure 100. The metal layer may include Ti, Ni, Ru, Co, W, or other suitable metal. The metal layer may be deposited by any suitable process, such as ALD, CVD, or PVD. After the metal layer deposition, an annealing process is performed to react the S/D regions 146 with the metal layer, thereby forming the silicide layers 182. The silicide layer 192 may include any suitable material, such as NiSi, TiSi, CoSi, RuSi, or wSi. A planarization process, such as a CMP process, may be performed so the top surfaces of the gate electrode layers 172 and the top surfaces of the conductive contacts 180 are substantially co-planar, as shown in FIG. 12A. In some embodiments, the conductive contact 180 has a critical dimension ranging from about 5 nm to about 50 nm.

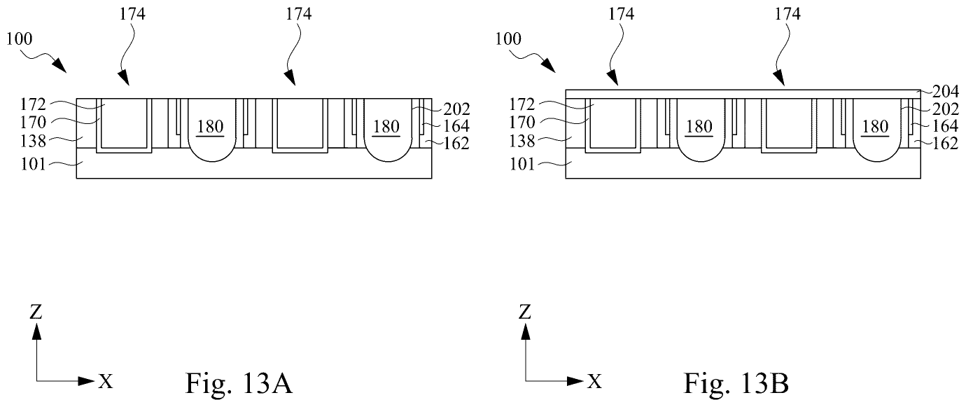

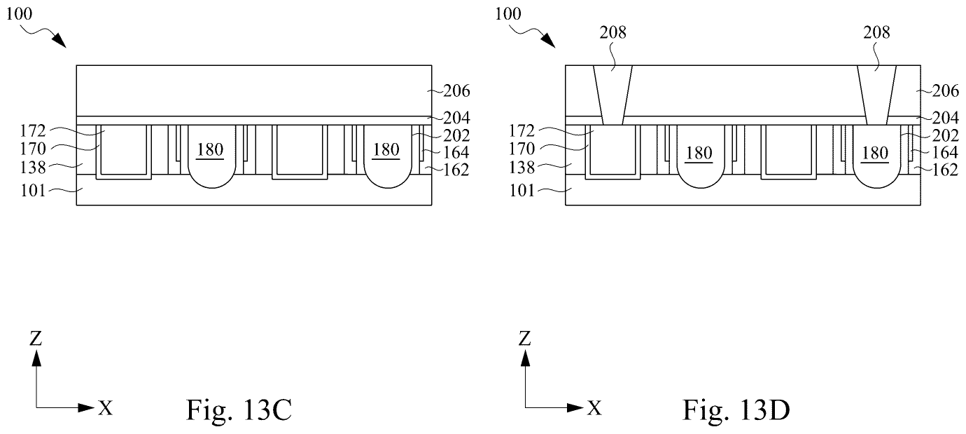

FIGS. 13A-13D are cross-sectional side views of various stages of manufacturing the semiconductor device structure 100 taken along line A-A of FIG. 6, in accordance with some embodiments. Various components on the substrate 101 are omitted in FIGS. 13A-13D for clarity. As shown in FIG. 13A, in some embodiments, the conductive contact 180 is formed between a liner 202. The liner may include any suitable dielectric material, such as SiN. In some embodiments, the liner 202 is not present, and the conductive contact 180 is in contact with the ILD layer 164. Next, as shown in FIG. 13B, an etch stop layer 204 is formed on the ILD layer 164, the gate structures 174, and the conductive contacts 180. The etch stop layer 204 may be referred to as a middle contact etch stop layer (MCESL). In some embodiments, the etch stop layer 204 may include a material different from the CESL 162. For example, the CESL 162 is made from SiN, and the etch stop layer 204 is made from a dielectric material having a k value less than that of the CESL 162. In some embodiments, the etch stop layer 204 includes SiCN. For example, the etch stop layer 204 includes a material having about 35 to 45 weight percent of silicon, 20 to 30 weight percent of carbon, and 30 to 40 weight percent of nitrogen. With the above composition, the etch stop layer 204 has a k value of about 4 to about 5, which is substantially lower than the k value of SiN, and the density of the etch stop layer 204 is greater than about 1.9 g/cm³, such as from about 1.9 g/cm³ to about 2 g/cm³. The reduced k value of the etch stop layer 204 can lead to capacitance (Ceff) reduction, which can improve one percent RO_AC and wafer acceptance test (WAT). In some embodiments, the etch stop layer 204 includes SiOCN. For example, the etch stop layer 204 includes a material having about 35 to 45 weight percent of silicon, 20 to 30 weight percent of oxygen, 10 to 20 weight percent of carbon, and 20 to 30 weight percent of nitrogen. With the above composition, the etch stop layer 204 has a k value of about less than 4.5, such as from about 4 to about 4.5, which is substantially lower than the k value of SiN, and the density of the etch stop layer 204 is greater than about 2 g/cm³, such as from about 2 g/cm³ to about 2.5 g/cm³. With the increased density, the etch stop layer 204 can block oxygen diffusion from the subsequently formed ILD layer 206 into the gate structures 174 and the conductive contacts 180.

In some embodiments, the etch stop layer 204 is a SiCN layer and is formed by PECVD using tetramethylsilane (TMS) as precursor. NH₃ plasma may be utilized to better dissociate TMS. In some embodiments, the etch stop layer 204 is a SiOCN layer and is formed by PECVD using dimethyldimethoxysilane (DMDMOS) as precursor. NH₃ plasma may be also utilized to better dissociate DMDMOS. In some embodiments, the processes to form the etch stop layer 204 and the ILD layer 206 (FIG. 13C) are PECVD processes, and the etch stop layer 204 and the ILD layer 206 are formed in the same process chamber without breaking vacuum to move the substrate to another chamber.

In some embodiments, the etch stop layer 204 has a thickness ranging from about 2.5 nm to about 3.5 nm. If the thickness of the etch stop layer 204 is less than about 2.5 nm, the etch stop layer 204 may not effectively reduce the Ceff and block oxygen. On the other hand, if the thickness of the etch stop layer 204 is greater than about 3.5 nm, the process to form an opening in the ILD layer 206 (FIG. 13C) and the etch stop layer 204 for the conductive features 208 (FIG. 13D) may take longer. Furthermore, the etch stop layer 204 can lead to smaller gate resistance due to larger CD of the conductive feature 208. For example, the SiCN or SiCON material of the etch stop layer 204 has a faster etch rate during the process to form the opening in the ILD layer 206. As a result, the bottom critical dimension of the opening in the ILD layer 206 is larger due to the faster etch rate of the etch stop layer 204, which leads to a larger conductive feature 208 (FIG. 13D).

As shown in FIG. 13C, another ILD layer 206 is deposited on the etch stop layer 204. The ILD layer 206 may include the same material as the ILD layer 164. Next, as shown in FIG. 13D, conductive features 208 are deposited in the ILD layer 206 and the etch stop layer 204. The conductive feature 208 may include an electrically conductive material, such as Ru, Mo, Co, Ir, W, Ti, Ta, Cu, TiN, TaN or combinations thereof, or other suitable material. The conductive feature 208 may be formed by any suitable process, such as PVD or ECP. In some embodiments, the conductive feature 208 is electrically connected to the gate electrode layers 172 and/or the conductive contacts 180.

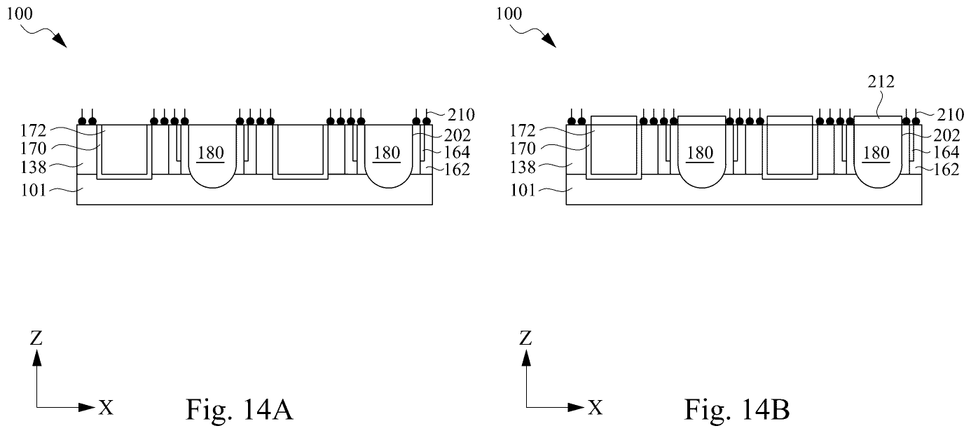

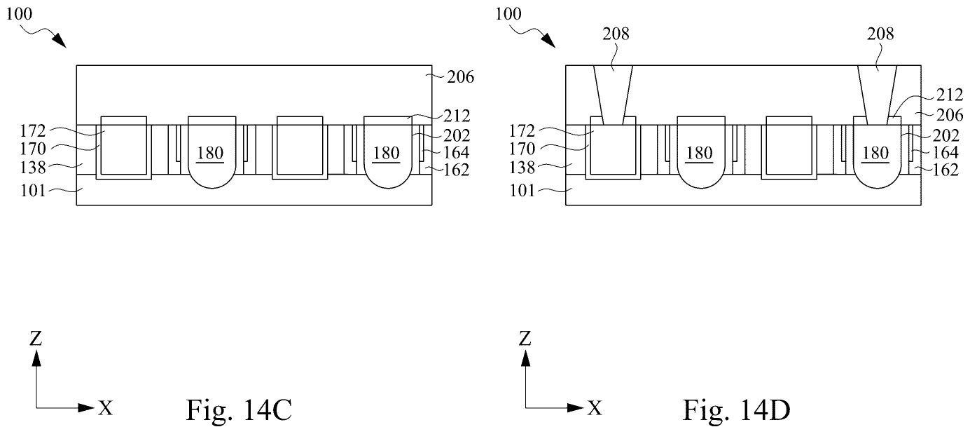

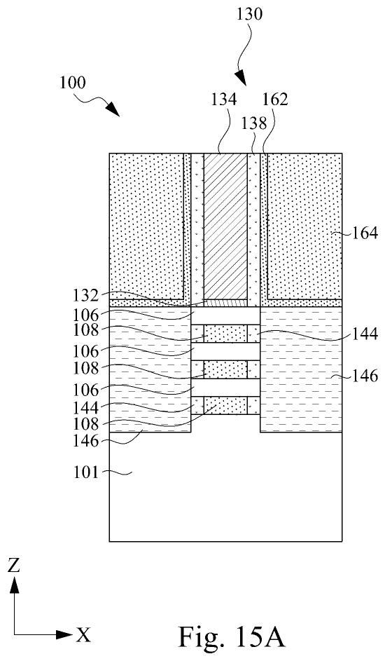

FIGS. 14A-14D are cross-sectional side views of various stages of manufacturing the semiconductor device structure 100 taken along line A-A of FIG. 6, in accordance with alternative embodiments. As shown in FIG. 14A, after the formation of the conductive contacts 180, a blocking layer 210 is selectively formed on the dielectric materials but not on the metallic surfaces. For example, the blocking layer 210 is selectively formed on the liner 202, the ILD layer 164, the CESL 162, the gate dielectric layers 170, and the spacers 138, but is not formed on the conductive contacts 180 and the gate electrode layers 172. The blocking layer 210 may include a polymer including silicon, carbon, nitrogen, oxygen or a combination thereof. In some embodiments, the blocking layer 210 is a silane based self-assembled monolayer (SAM). In some embodiments, the silane based SAM may include Octadecyltrichlorosilane (ODTS), Octadecyltrimethoxysilane (OTMS), (3-Aminopropyl)triethoxysilane (APTES), Butyltriethoxysilane, Cyclohexyltrimethoxysilane, Cyclopentyltrimethoxysilane, Dodecyltriethoxysilane, Dodecyltrimethoxysilane, Decyltriethoxysilane, Dimethoxy(methyl)-n-octylsilane, Triethoxyethylsilane, Ethyltrimethoxysilane, Hexyltrimethoxysilane, Hexyltriethoxysilane, Hexadecyltrimethoxysilane, Hexadecyltriethoxysilane, Triethoxymethylsilane, Trimethoxy(methyl)silane, Methoxy(dimethyl)octadecylsilane, Methoxy(dimethyl)-n-octylsilane, Octadecyltriethoxysilane, Triethoxy-n-octylsilane, Trimethoxy (propyl) silane, Trimethoxy-n-octylsilane, Tricthoxy(propyl)silane, or other suitable compound. In some embodiments, the blocking layer 210 may be formed by CVD, molecular layer deposition (MLD), or other suitable process.

As shown in FIG. 14B, after forming the blocking layer 210, an etch stop layer 212 is selectively formed on the metallic surfaces of the conductive contacts 180 and the gate electrode layers 172. In some embodiments, the etch stop layer 212 includes the same material as the etch stop layer 204. Because the hydrophilic/hydrophobic characteristics of the blocking layer 210, the etch stop layer 212 is prevented from being formed on the blocking layer 210, and therefore the etch stop layer 212 is formed on the areas not covered by the blocking layer 210. Thus, in some embodiments, the etch stop layer 212 is selectively formed on the conductive contacts 180 and the gate electrode layers 172 to provide a stop point for the subsequent etch process to form the openings for the conductive features 208, to block oxygen diffusion from the subsequently formed ILD layer 206 into the conductive contacts 180 and the gate electrode layers 172, and to lower the Ceff. No etch stop layer is formed on the spacers 138, the ILD layer 164, the CESL 162, the gate dielectric layers 170, and the liner 202 because there is no need for a stop point at those locations in the subsequent etch process, there is no risk of oxidation of a metal at those locations, and the k value of the ILD layer 206 is substantially lower than that of the etch stop layer 212, which further reduces the Ceff.

As shown in FIG. 14C, after the formation of the etch stop layer 212, the blocking layer 210 is removed. In some embodiments, the blocking layer 210 may be removed by a dry etch process, a wet etch process or other suitable processes. After the removal of the blocking layer 210, the etch stop layer 212 remained on the gate electrode layers 172 and the conductive contacts 180. The ILD layer 206 is formed on the spacers 138, the gate dielectric layer 170, the CESL 162, the ILD layer 164, the liner 202, and the etch stop layer 212, as shown in FIG. 14C. Next, as shown in FIG. 14D, the conductive features 208 are formed in the ILD layer 206 and the etch stop layer 212.

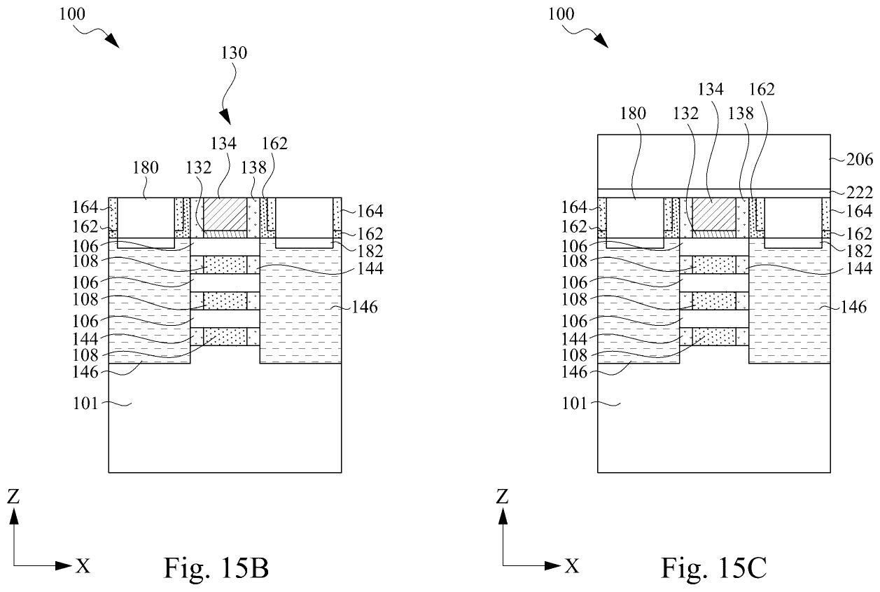

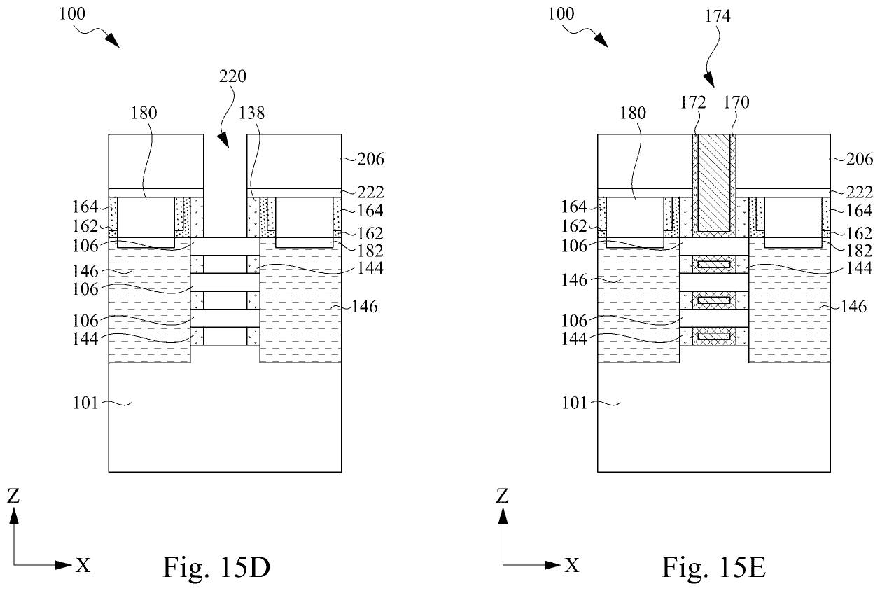

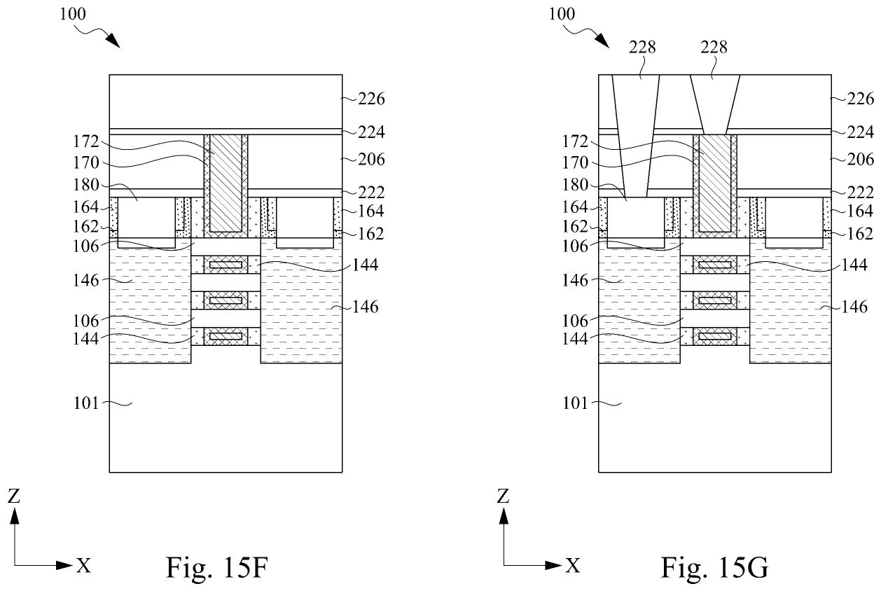

FIGS. 15A-15G are cross-sectional side views of various stages of manufacturing the semiconductor device structure 100 taken along line A-A of FIG. 6, in accordance with alternative embodiments. As shown in FIG. 15A, the CESL 162 and the ILD layer 164 are formed over the S/D regions 146. Next, as shown in FIG. 15B, the conductive contacts 180 and the silicide layers 182 are formed. A planarization process, such as a CMP process, may be performed to remove portions of the conductive contacts 180 formed on the sacrificial gate electrode layers 134. As shown in FIG. 15C, an etch stop layer 222 and the ILD layer 206 are formed on the conductive contacts 180 and the sacrificial gate electrode layers 134. In some embodiments, the etch stop layer 222 includes the same material as the CESL 162. In some embodiments, the etch stop layer 222 includes the same material as the etch stop layer 204, which can lead to reduced Ceff. As shown in FIG. 15D, an opening 220 is formed in the ILD layer 206 and the etch stop layer 222, and the opening 220 extends to between the spacers 138 and the first semiconductor layers 106. In other words, portions of the ILD layer 206 and the etch stop layer 222, along with the sacrificial gate electrode layer 134, sacrificial gate dielectric layer 132, and the second semiconductor layers 108 are removed to form the opening 220. Next, as shown in FIG. 15E, the gate dielectric layer 170 and the gate electrode layer 172 are formed in the opening 220. Another etch stop layer 224 and another ILD layer 226 are formed on the ILD layer 206, the gate dielectric layer 170, and the gate electrode layer 172, as shown in FIG. 15F. In some embodiments, the etch stop layer 224 includes the same material as the etch stop layer 204. As a result, Ceff is reduced, and oxygen diffusion from the ILD layer 226 into the gate electrode layer 172 is prevented. Next, as shown in FIG. 15G, conductive features 228 are formed in the ILD layer 226, the etch stop layer 224, the ILD layer 206, and the etch stop layer 222. The conductive features 228 may include the same material as the conductive features 208. In some embodiments, one conductive feature 228 is electrically connected to the gate electrode layer 172, and another conductive feature 228 is electrically connected to the conductive contact 180, as shown in FIG. 15G.

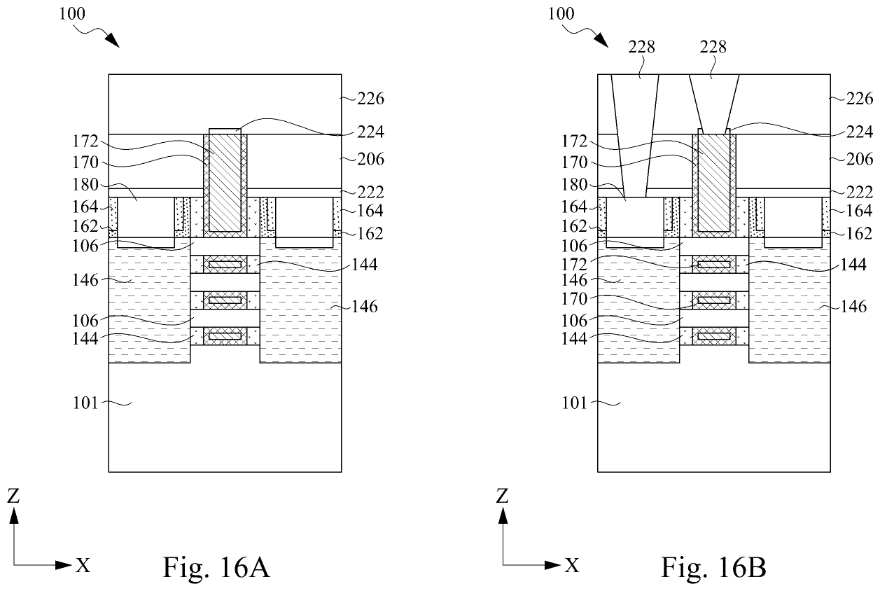

FIGS. 16A and 16B are cross-sectional side views of various stages of manufacturing the semiconductor device structure 100 taken along line A-A of FIG. 6, in accordance with alternative embodiments. In some embodiments, the etch stop layer 224 is selectively formed on the gate electrode layer 172, as shown in FIG. 16A. The etch stop layer 224 may be selectively formed on the gate electrode layer 172 using a blocking layer (not shown), for example the blocking layer 210 shown in FIG. 14A. The blocking layer may be first formed on the dielectric materials of the ILD layer 206 and the gate dielectric layer 170, and the blocking layer is removed after the etch stop layer 224 is selectively formed on the gate electrode layer 172. The etch stop layer 224 prevents oxygen diffusion from the ILD layer 226 into the gate electrode layer 172. In some embodiments, the ILD layer 226 is in direct contact with the ILD layer 206, as shown in FIG. 16A. In some embodiments, when forming the openings for the conductive features 208, the etch stop layers 224, 222 provide a stop point for the etch process. Thus, even though the opening for the conductive feature 208 disposed over the conductive contact 180 is deeper than the opening for the conductive feature 208 disposed over the gate electrode layer 172, over-etching is prevented as a result of having the etch stop layers 224, 222. In some embodiments, the etch stop layers 222, 224 include the same material, such as SiCN or SiOCN, and the portions of the etch stop layers 222, 224 are removed simultaneously. In other words, a single etch process may be performed to remove portions of the etch stop layers 222, 224 to expose the conductive contact 180 and the gate electrode layer 172. Next, as shown in FIG. 16B, the conductive features 228 are formed in the openings over the conductive contacts 180 and the gate electrode layer 172.

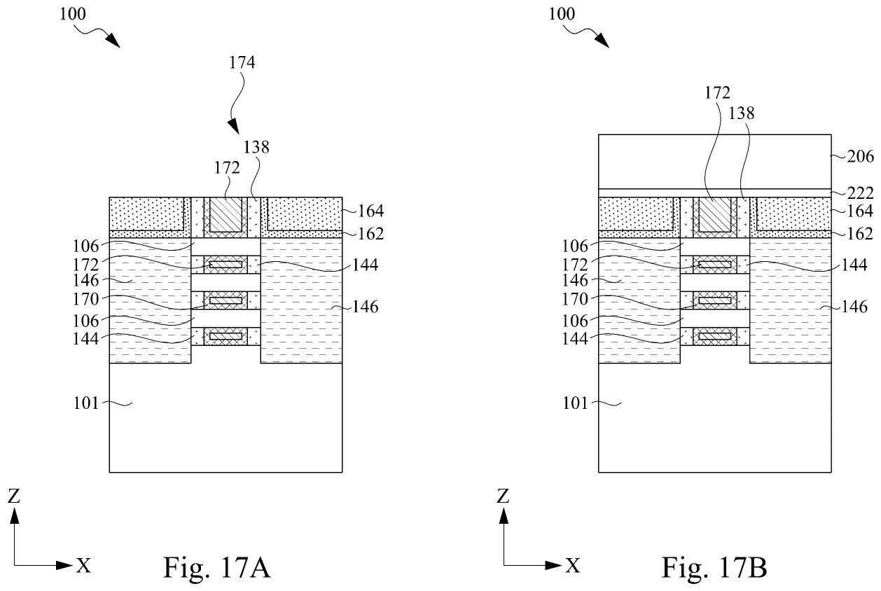

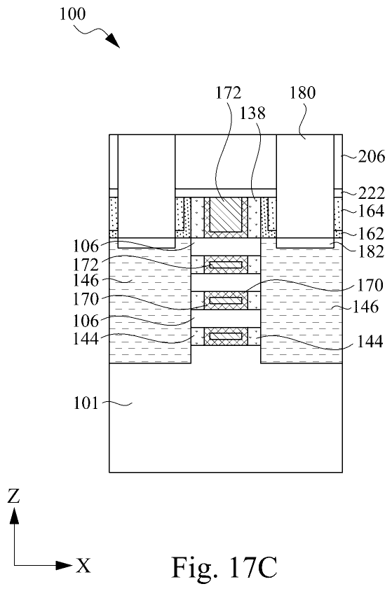

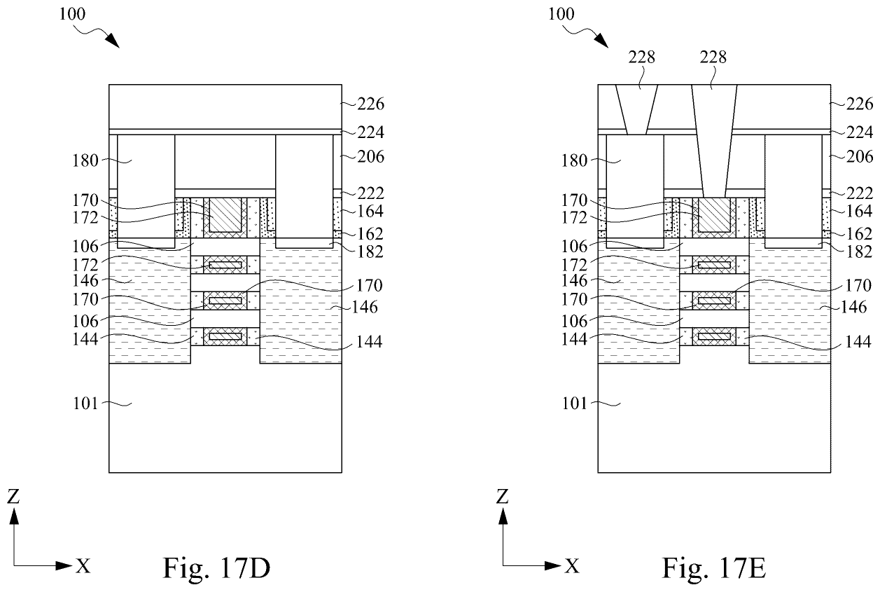

FIGS. 17A-17E are cross-sectional side views of various stages of manufacturing the semiconductor device structure 100 taken along line A-A of FIG. 6, in accordance with alternative embodiments. As shown in FIG. 17A, after forming the gate structure 174, a CMP process is performed to remove portions of the gate electrode layer 172 formed on the ILD layer 164. Next, as shown in FIG. 17B, the etch stop layer 222 and the ILD layer 206 are formed on the ILD layer 164 and the gate structures 174. In some embodiments, the etch stop layer 222 includes the same material as the etch stop layer 204. Thus, the etch stop layer 222 provides a stop point for the subsequently performed etch process, reduces the Ceff, and prevents oxygen diffusion from the ILD layer 206 into the gate electrode layer 172. As shown in FIG. 17C, the conductive contacts 180 are formed in the ILD layer 206 and the etch stop layer 222, and the silicide layers 182 are formed between the conductive contacts 180 and the S/D regions 146. Next, the etch stop layer 224 and the ILD layer 226 are formed on the conductive contacts 180 and the ILD layer 206, as shown in FIG. 17D. In some embodiments, the etch stop layer 224 includes the same material as the etch stop layer 204. Thus, the etch stop layer 224 provides a stop point for the subsequently performed etch process, reduces the Ceff, and prevents oxygen diffusion from the ILD layer 226 into the conductive contacts 180. Next, as shown in FIG. 17E, the conductive features 228 are formed in the ILD layer 226, the etch stop layer 224, the ILD layer 206, and the etch stop layer 222. The conductive feature 228 is electrically connected to the gate electrode layer 172 and the conductive contact 180.

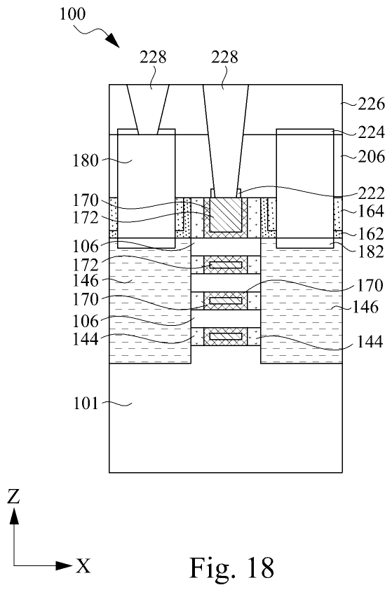

FIG. 18 is a cross-sectional side view of one of various stages of manufacturing the semiconductor device structure 100 taken along line A-A of FIG. 6, in accordance with alternative embodiments. In some embodiments, the etch stop layer 222 is selectively formed on the gate electrode layer 172, and the etch stop layer 224 is selectively formed on the conductive contacts 180, as shown in FIG. 18. Thus, the etch stop layers 222, 224 provide stop points for the subsequent etch process to form the openings for the conductive features 208, block oxygen diffusion from the ILD layers 206, 226 into the gate electrode layer 172 and the conductive contacts 180, and lower the Ceff. No etch stop layer is formed on the dielectric materials because there is no need for a stop point at those locations in the subsequent etch process, there is no risk of oxidation of a metal at those locations, and the k value of the ILD layers 206, 226 is substantially lower than that of the etch stop layers 222, 224, which further reduces the Ceff.

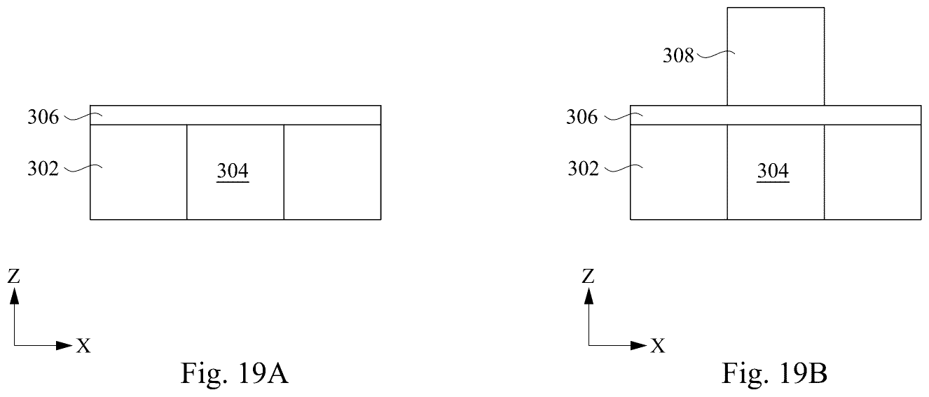

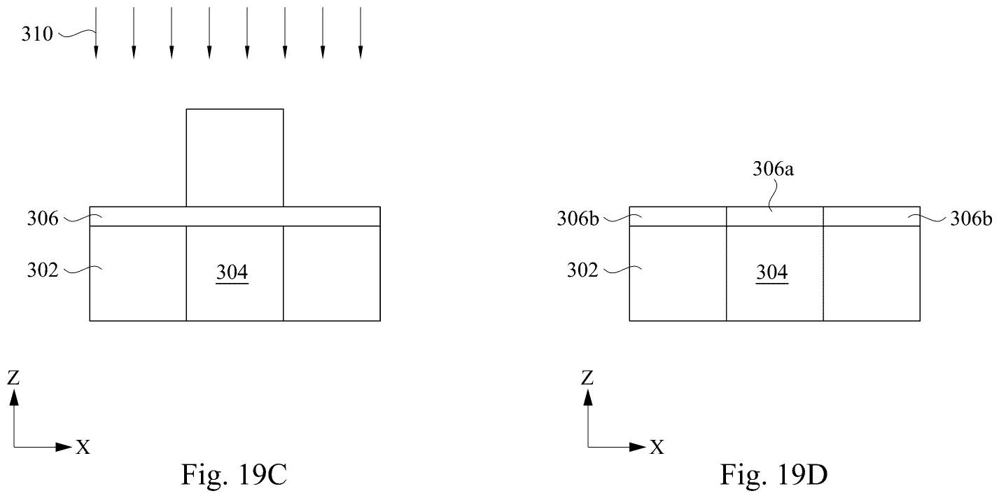

FIGS. 19A-19D are cross-sectional side views of various stages of manufacturing the semiconductor device structure 100 taken along line A-A of FIG. 6, in accordance with alternative embodiments. In some embodiments, a conductive feature 304 is formed in a dielectric layer 302. The conductive feature 304 may be the gate electrode layer 172 or the conductive contact 180, and the dielectric layer 302 may be the ILD layer 164, the ILD layer 206, or the ILD layer 226. An etch stop layer 306 is deposited on the dielectric layer 302 and the conductive feature 304. In some embodiments, the etch stop layer 306 is made of SiN and has a k value of about 7. Next, as shown in FIG. 19B, a mask layer 308 is formed on a portion of the etch stop layer 306 disposed on the conductive feature 304. Portions of the etch stop layer 306 located on the dielectric layer 302 are exposed.

As shown in FIG. 19C, an implantation process 310 is preformed to implant a dopant into the exposed portions of the etch stop layer 306 to lower the k value thereof. In some embodiments, the dopant includes carbon. In some embodiments, the dopant includes carbon and oxygen. After the implantation process, the mask layer 308 is removed, and the etch stop layer 306 includes a first portion 306a disposed on the conductive feature 304 and a second portion 306b disposed on the dielectric layer 302, as shown in FIG. 19D. The first portion 306a and the second portion 306b have different compositions. For example, the first portion 306a includes SiN without a dopant, and the second portion 306b includes carbon doped SiN or carbon and oxygen doped SiN. In some embodiments, the first portion 306a includes SiN having a first k value and a first density, and the second portion 306b includes SiCN or SiOCN having a second k value and a second density. The second k value may be substantially less than the first k value, and the second density may be substantially less than the first density. The second k value can lead to reduced Ceff. Even though the oxygen blocking property of the second portion 306b is inferior to the oxygen blocking property of the first portion 306a, there is no metal located below the second portion 306b. Thus, the risk of oxidation of a metal is non-existent. The etch stop layer 306 including the first portion 306a and the second portion 306b may replace the etch stop layer 204 shown in FIG. 13D, the etch stop layer 222 shown in FIGS. 15G, 16B, 17E, and the etch stop layer 224 shown in FIG. 15G, 16B, 17E. When used as the etch stop layer 204, 222, or 224, the first portion 306a of the etch stop layer 306 is disposed over conductive materials, such as the conductive contacts 180 and/or the gate electrode layer 172, and the second portion 306b of the etch stop layer is disposed over dielectric materials, such as the ILD layer 164, the ILD layer 206, and/or the ILD layer 226.

Embodiments of the present disclosure provide a semiconductor device structure 100 including an etch stop layer 204 that is made of SiCN or SiOCN. Some embodiments may achieve advantages. For example, the k value of the etch stop layer 204 is lower than that of a conventional etch stop layer, while the density of the etch stop layer 204 is high enough to prevent oxygen diffusion from a dielectric material disposed on the etch stop layer 204 into a conductive feature disposed below the etch stop layer 204. The lowered k value can lead to reduced Ceff.

An embodiment is a semiconductor device structure. The structure includes a gate electrode layer disposed over a substrate, a source/drain region disposed over the substrate, a conductive contact disposed over the source/drain region, a first etch stop layer disposed on the conductive contact and the gate electrode layer, and the first etch stop layer includes SiCN or SiOCN. The structure further includes a first dielectric layer disposed on the first etch stop layer, a first conductive feature disposed in the first dielectric layer and the first etch stop layer, and the first conductive feature is electrically connected to the conductive contact. The structure further includes a second conductive feature disposed in the first dielectric layer and the first etch stop layer, and the second conductive feature is electrically connected to the gate electrode layer.

Another embodiment is a semiconductor device structure. The structure includes a source/drain region disposed over a substrate, a conductive contact disposed over the source/drain region, a first etch stop layer disposed on the conductive contact, and the first etch stop layer comprises SiCN or SiOCN. The structure further includes a first dielectric layer disposed on the first etch stop layer, a gate electrode layer disposed through the first dielectric layer and the first etch stop layer, a second etch stop layer disposed on the gate electrode layer, a second dielectric layer disposed on the second etch stop layer, a first conductive feature disposed in the first dielectric layer, the first etch stop layer, and the second dielectric layer, and the first conductive feature is electrically connected to the conductive contact. The structure further includes a second conductive feature disposed in the second dielectric layer and the second etch stop layer, and the second conductive feature is electrically connected to the gate electrode layer.

A further embodiment is a method. The method includes performing a planarization process to expose a gate electrode layer, a conductive contact, and a spacer and selectively depositing a first etch stop layer on the gate electrode layer and the conductive contact. The first etch stop layer comprises SiCN or SiOCN. The method further includes depositing a first dielectric layer on the first etch stop layer and the spacer and forming first and second conductive features in the first dielectric layer and the first etch stop layer. The first conductive feature is electrically connected to the gate electrode layer, and the second conductive feature is electrically connected to the conductive contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a gate electrode layer disposed over a substrate;
a source/drain region disposed over the substrate;
a conductive contact disposed over the source/drain region;
a first etch stop layer disposed on the conductive contact and the gate electrode layer, wherein the first etch stop layer comprises SiCN or SiOCN;
a first dielectric layer disposed on the first etch stop layer;
a first conductive feature disposed in the first dielectric layer and the first etch stop layer, wherein the first conductive feature is electrically connected to the conductive contact; and
a second conductive feature disposed in the first dielectric layer and the first etch stop layer, wherein the second conductive feature is electrically connected to the gate electrode layer.

2. The semiconductor device structure of claim 1, further comprising a second etch stop layer disposed over the source/drain region, wherein the conductive contact is disposed in the second etch stop layer.

3. The semiconductor device structure of claim 2, wherein the first and second etch stop layers comprise different materials.

4. The semiconductor device structure of claim 1, wherein the first etch stop layer further comprises 35 to 45 weight percent of silicon, 20 to 30 weight percent of carbon, and 30 to 40 weight percent of nitrogen.

5. The semiconductor device structure of claim 1, further comprising a second dielectric layer, wherein the conductive contact is disposed in the second dielectric layer.

6. The semiconductor device structure of claim 5, wherein the first etch stop layer is in contact with the second dielectric layer.

7. The semiconductor device structure of claim 5, wherein the first dielectric layer is in contact with the second dielectric layer.

8. A semiconductor device structure, comprising:
a source/drain region disposed over a substrate;
a conductive contact disposed over the source/drain region;
a first etch stop layer disposed on the conductive contact, wherein the first etch stop layer comprises SiCN or SiOCN;
a first dielectric layer disposed on the first etch stop layer;
a gate electrode layer disposed through the first dielectric layer and the first etch stop layer;
a second etch stop layer disposed on the gate electrode layer;
a second dielectric layer disposed on the second etch stop layer;
a first conductive feature disposed in the first dielectric layer, the first etch stop layer, and the second dielectric layer, wherein the first conductive feature is electrically connected to the conductive contact; and
a second conductive feature disposed in the second dielectric layer and the second etch stop layer, wherein the second conductive feature is electrically connected to the gate electrode layer.

9. The semiconductor device structure of claim 8, wherein the second etch stop layer comprises SiCN or SiOCN.

10. The semiconductor device structure of claim 8, wherein the second etch stop layer comprises a first portion disposed on and in contact with the gate electrode layer and a second portion disposed on and in contact with the first dielectric layer, and the first portion and the second portion have different compositions.

11. The semiconductor device structure of claim 10, wherein the first portion of the second etch stop layer comprises SiN, and the second portion of the second etch stop layer comprises carbon doped SiN or carbon and oxygen doped SiN.

12. The semiconductor device structure of claim 8, further comprising a third etch stop layer disposed over the source/drain region, wherein the conductive contact is disposed in the third etch stop layer.

13. The semiconductor device structure of claim 12, wherein a k value of the third etch stop layer is greater than a k value of the first etch stop layer.

14. The semiconductor device structure of claim 8, wherein the second dielectric layer is disposed on and in contact with the first dielectric layer.

15. A method, comprising:
performing a planarization process to expose a gate electrode layer, a conductive contact, and a spacer;
selectively depositing a first etch stop layer on the gate electrode layer and the conductive contact, wherein the first etch stop layer comprises SiCN or SiOCN;
depositing a first dielectric layer on the first etch stop layer and the spacer; and
forming first and second conductive features in the first dielectric layer and the first etch stop layer, wherein the first conductive feature is electrically connected to the gate electrode layer, and the second conductive feature is electrically connected to the conductive contact.

16. The method of claim 15, wherein the planarization process further exposes a second dielectric layer and a second etch stop layer.

17. The method of claim 16, wherein a k value of the second etch stop layer is greater than a k value of the first etch stop layer.

18. The method of claim 16, wherein selectively depositing of the etch stop layer comprises selectively depositing a blocking layer on the spacer, the second dielectric layer, and the second etch stop layer.

19. The method of claim 18, further comprising removing the blocking layer.

20. The method of claim 15, wherein the first etch stop layer and the first dielectric layer are deposited in a same process chamber.
